(19) United States
(12) Patent Application Publication
(10) Pub. No.: US 2024/0387612 A1
(43) Pub. Date: Nov. 21, 2024

(54) CAPACITOR AND SEMICONDUCTOR DEVICE INCLUDING THE SAME

(71) Applicant: Samsung Electronics Co., Ltd., Suwon-si (KR)

(72) Inventors: Kyooho Jung, Suwon-si (KR); Jongyeong Min, Suwon-si (KR); Joonsuk Park, Suwon-si (KR); Jiye Baek, Suwon-si (KR); Yeseul Lee, Suwon-si (KR); Jinwook Lee, Suwon-si (KR)

(21) Appl. No.: 18/633,456

(22) Filed: Apr. 11, 2024

(30) Foreign Application Priority Data
May 15, 2023 (KR) 10-2023-0062496

(51) Int. Cl. H10B 12/00; C23C 16/34

(52) U.S. Cl. CPC H01L 28/75; C23C 16/34; H10B 12/315; H10B 12/482

(57) ABSTRACT

A semiconductor device may include a substrate and a capacitor on the substrate. The capacitor may include a lower electrode, a dielectric layer on the lower electrode, a first upper electrode on the dielectric layer, and a second upper electrode on the first upper electrode. The dielectric layer may include a metal oxide. The first upper electrode may include a metal nitride further including a first material having a work function of 4.8 eV or more. The second upper electrode may include the first material.

### CROSS-REFERENCE TO RELATED APPLICATION(S)

This application claims priority under 35 USC § 119 to Korean Patent Application No. 10-2023-0062496, filed on May 15, 2023, in the Korean Intellectual Property Office (KIPO), the disclosure of which is incorporated by reference herein in its entirety.

### BACKGROUND

### 1. Field

Example embodiments relates to a capacitor and a semiconductor device including the capacitor.

### 2. Description of the Related Art

A capacitor included in a semiconductor device may be required to have high electrostatic capacitance. To this end, a thickness of a dielectric layer of the capacitor may decrease. However, as the thickness of the dielectric layer of the capacitor decreases, leakage current may increase. Therefore, it is desired that the capacitor may have high capacitance and low leakage current.

### SUMMARY

Example embodiments provide a capacitor having excellent characteristics.

Example embodiments provide a semiconductor device having a capacitor having excellent characteristics.

According to example embodiments, a semiconductor device may include a substrate and a capacitor on the substrate. The capacitor may include a lower electrode, a dielectric layer on the lower electrode, a first upper electrode on the dielectric layer, and a second upper electrode on the first upper electrode. The dielectric layer may include a metal oxide. The first upper electrode may include a metal nitride further including a first material having a work function of 4.8 eV or more. The second upper electrode may include the first material.

According to example embodiments, a semiconductor device may include a substrate, a lower structure on the substrate, and capacitors on the structure. The capacitors may include a plurality of lower electrodes on the lower structure, a dielectric layer on surfaces of the lower electrodes and the lower structure, a first upper electrode on the dielectric layer, and a second upper electrode partially covering a surface of the first upper electrode. Each of the lower electrodes may have a pillar shape. The first upper electrode may cover an entire surface of the dielectric layer, and the first upper electrode may include a metal nitride further including a first material having a work function higher than a work function of the metal nitride. The second upper electrode may include the first material. A portion of the dielectric layer and a space in contact with the portion of the dielectric layer may be formed between the lower electrodes. The first upper electrode and the second upper electrode may partially fill the space between the lower electrodes.

According to example embodiments, a semiconductor device may include cell transistors on a substrate, bit line structures, first conductive patterns on the bit line structures, second conductive patterns between the bit line structures, and capacitors disposed on the first conductive patterns. The cell transistor may include a gate structure, a first impurity region, and a second impurity region. The bit line structures may be respectively electrically connected to the first impurity region of each of the cell transistors. The second conductive patterns may be respectively electrically connected to each of the first conductive patterns and the second impurity region of each of the cell transistors. The capacitors include lower electrodes having pillar shapes, a dielectric layer on surfaces of the lower electrodes, a first upper electrode covering an entire surface of the dielectric layer, and a second upper electrode forming discontinuously on a surface of the first upper electrode. The lower electrodes may contact the first conductive patterns, respectively. The first upper electrode may include a metal nitride further including a first material having a work function of 4.8 eV or more. The second upper electrode may include the first material.

In the capacitor according to example embodiments, the upper electrode may have a high work function. Therefore, leakage current between the dielectric layer and the upper electrode in the capacitor may be decreased.

### BRIEF DESCRIPTION OF THE DRAWINGS

Example embodiments will be more clearly understood from the following detailed description taken in conjunction with the accompanying drawings. FIGS. 1 to 30 represent non-limiting, example embodiments as described herein.

FIG. 1 is a cross-sectional view illustrating a capacitor according to example embodiments;

FIG. 2 is an enlarged cross-sectional view illustrating the capacitor shown in FIG. 1 according to example embodiments;

FIG. 3 illustrates a concentration of a first material included in a first upper electrode of the capacitor of FIG. 2 according to example embodiments;

FIG. 4 is a cross-sectional view illustrating a capacitor according to example embodiments;

FIG. 5 is an enlarged cross-sectional view illustrating the capacitor shown in FIG. 4 according to example embodiments;

FIGS. 6 to 12 are cross-sectional views illustrating a method for forming a capacitor according to example embodiments;

FIG. 13 is a cross-sectional view illustrating capacitors according to example embodiments;

FIG. 14 is a cross-sectional view illustrating a capacitor according to example embodiments;

FIGS. 15 to 23 are cross-sectional views illustrating a method for forming a capacitor according to example embodiments;

FIG. 24 is a plan view illustrating a layout of a semiconductor device according to example embodiments;

FIG. 25 is a cross-sectional view of a semiconductor device according to example embodiments;

FIGS. 26 and 27 are cross-sectional views illustrating a method for manufacturing a semiconductor device according to example embodiments;

FIG. 28 is a layout illustrating a semiconductor device according to example embodiments;

FIG. 29 is a cross-sectional view illustrating a semiconductor device according to example embodiments; and

FIG. 30 illustrates leakage current characteristics of a capacitor according to an embodiment and a capacitor according to a comparative example.

### DETAILED DESCRIPTION OF THE EMBODIMENTS

Hereinafter, embodiments of the present invention will be described in detail with reference to the accompanying drawings.

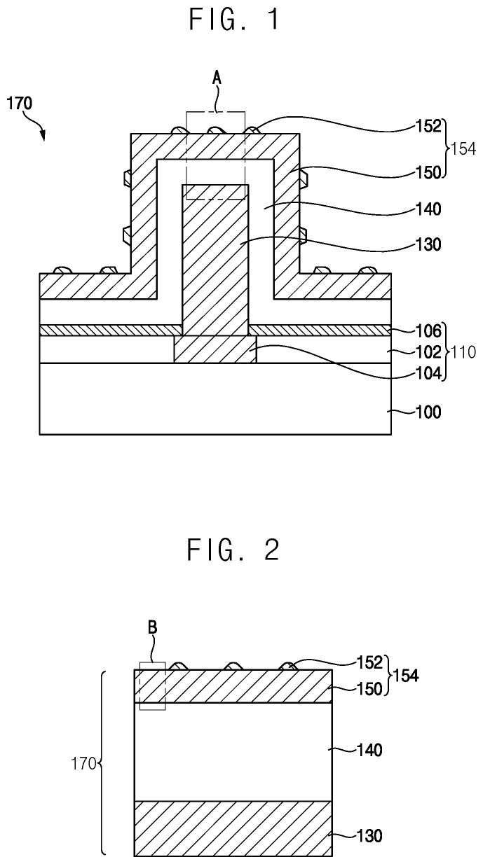

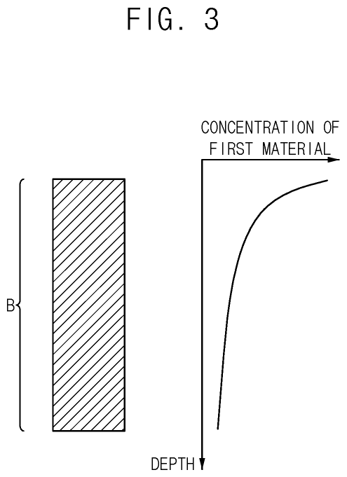

FIG. 1 is a cross-sectional view illustrating a capacitor according to example embodiments. FIG. 2 is an enlarged cross-sectional view illustrating the capacitor shown in FIG. 1 according to example embodiments. FIG. 3 illustrates a concentration of a first material included in a first upper electrode of the capacitor of FIG. 2 according to example embodiments.

Particularly, FIG. 1 is the vertical cross-sectional view of the capacitor having a lower electrode of a pillar-shape. FIG. 2 is an enlarged cross-sectional view of a portion A of FIG. 1. FIG. 3 is the concentration of the first material from an upper surface of the first upper electrode to a bottom surface of the first upper electrode in region B of FIG. 2.

Referring to FIGS. 1 and 2, the capacitor 170 may include a lower electrode 130, a dielectric layer 140, and an upper electrode 154. The upper electrode 154 may include a first upper electrode 150 and a second upper electrode 152.

In example embodiments, the capacitor 170 may be formed on a lower structure 110 on a substrate 100. The lower structure 110 may include, e.g., a transistor, a contact plug, a conductive pattern 104, a conductive line, an insulating interlayer 102, and an etch stop layer 106. The conductive pattern 104 may contact a bottom of the lower electrode 130. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact. The etch stop layer 106 may be formed on the conductive pattern 104 and the insulating interlayer 102.

The substrate 100 may include, e.g., a semiconductor material such as silicon, germanium, silicon-germanium, etc., or a group III-V compound such as GaP, GaAs, GaSb, etc. In some example embodiments, the substrate 100 may be a Silicon On Insulator (SOI) substrate or a Germanium On Insulator (GOI) substrate.

The lower electrode 130 may pass through the etch stop layer 106, and may contact an upper surface of the conductive pattern 104.

The lower electrode 130 may include metal or metal nitride. In example embodiments, the lower electrode 130 may be formed of or include, e.g., titanium nitride (TiN), titanium silicon nitride (TiSiN), titanium (Ti), tantalum (Ta), tantalum nitride (TaN), tantalum silicon nitride (TaSiN), niobium nitride (NbN) or niobium silicon nitride (NbSiN). For example, the lower electrode 130 may be formed of or include titanium nitride (TiN).

The lower electrode 130 may have various three-dimensional structures.

In example embodiments, the lower electrode 130 may have a three-dimensional structure such as a cylinder shape or a pillar shape. As shown in FIG. 1, the lower electrode 130 may have the pillar shape. Alternatively, the lower electrode may have the cylindrical shape (i.e., a cup shape).

In some example embodiments, the lower electrode 130 may have a flat two-dimensional shape, and in this case, the capacitor may have a shape similar to the enlarged view shown in FIG. 2. A capacitance of the capacitor is determined by a surface area of the lower electrode 130. Therefore, the lower electrode 130 may have various modified structures so as to increase the capacitance of the capacitor.

The dielectric layer 140 may be formed of or include metal oxide. The dielectric layer 140 may be a high dielectric layer having a dielectric constant higher than a dielectric constant of silicon nitride.

In example embodiments, the dielectric layer 140 may be formed of or include, e.g., hafnium oxide, zirconium oxide, and/or aluminum oxide. The dielectric layer 140 may include one material, or the dielectric layer 140 may include two or more materials stacked. Alternatively, the dielectric layer 140 may include a composite material including two or more of the hafnium oxide, zirconium oxide, and aluminum oxide.

In example embodiments, a thickness of the dielectric layer 140 may be about 30 Å to about 60 Å. When the thickness of the dielectric layer 140 is less than 30 Å, leakage currents of the capacitor may occur. When the thickness of the dielectric layer 140 is greater than 60 Å, the capacitance of the capacitor may be decreased.

The upper electrode 154 may be formed on the dielectric layer 140.

The upper electrode 154 may include a first upper electrode 150 that contacts the dielectric layer 140 and covers an upper surface of the dielectric layer 140, and a second upper electrode 152 on the first upper electrode 150.

In example embodiments, the first upper electrode 150 may include metal nitride further including a first material inside. In example embodiments, the first upper electrode 150 may be formed of metal nitride and the first material. The first material may be a material having a work function higher than a work function of the metal nitride in the first upper electrode 150. In example embodiments, the first material may be a material having a work function of about 4.8 eV or more.

The metal nitride may be a material that can be continuously deposited on a surface of the dielectric layer 140 by a deposition process, e.g., an atomic layer deposition (ALD) process or a chemical vapor deposition (CVD) process. The metal nitride may be the material that can be uniformly deposited on the surface of the dielectric layer 140 to have a thickness of about 100 Å or less, by the deposition process, e.g., the ALD process or the CVD process.

In example embodiments, the metal nitride may include, e.g., TiN, TiSiN, TaN, TaSiN, NbN, or NbSiN. For example, the metal nitride may be the titanium nitride, and the first material may be a material having a work function higher than a work function of the titanium nitride.

In example embodiments, the first material may include, e.g., Ni, Pd, Ir, or Pt. In example embodiments, the first material may include one metal material or two or more metal materials.

For example, the first upper electrode 150 may include titanium nitride (TiN) further including Ni, Pd, Ir or Pt, or titanium silicon nitride (TiSiN) further including Ni, Pd, Ir or Pt. For example, the first upper electrode 150 may be formed of titanium nitride (TiN) and Ni, Pd, Ir or Pt, or titanium silicon nitride (TiSiN) and Ni, Pd, Ir or Pt.

As shown in FIG. 3, a concentration of the first material in the first upper electrode 150 may decrease in a direction from an upper surface (e.g., outer surface) of the first upper electrode 150 to the dielectric layer 140. The concentration of the first material in the first upper electrode 150 may gradually decrease from the upper surface of the first upper electrode 150 to an inside of the first upper electrode 150.

The first material may not be included in the dielectric layer 140.

In example embodiments, the first upper electrode 150 may have a thickness of about 20 Å to about 50 Å. When the thickness of the first upper electrode 150 is less than 20 Å, a depositing of the first upper electrode 150 continuously on the dielectric layer 140 may be difficult. When the thickness of the first upper electrode 150 is greater than 50 Å, sufficiently diffusing of the first material into the first upper electrode 150 may be difficult.

As the first upper electrode 150 may include the metal nitride further including the first material having the work function higher than the work function of the metal nitride, the first upper electrode 150 may have a work function higher than a work function of an upper electrode including only metal nitride. When the work function of the first upper electrode 150 increases, an energy band gap between the dielectric layer 140 and the first upper electrode 150 may increase. Therefore, leakage currents between the dielectric layer 140 and the first upper electrode 150 may decrease.

The second upper electrode 152 including the first material may be on the first upper electrode 150. The second upper electrode 152 may be discontinuously disposed on the upper surface of the first upper electrode 150, so that the second upper electrode 152 may not entirely cover the first upper electrode 150. The second upper electrode 152 may partially cover the first upper electrode 150. The second upper electrode 152 may collectively refer to a plurality of first materials having an isolated island shape arranged to be spaced apart from each other on the first upper electrode 150.

The second upper electrode 152 may include the first material the same as the first material included in the first upper electrode 150. The second upper electrode 152 may have a thickness less than the thickness of the first upper electrode 150. The thickness of the second upper electrode 152 may be a thickness of each of the first material. In example embodiments, the second upper electrode 152 may have the thickness of about 5 Å to about 30 Å.

A plate electrode may be further disposed on the first upper electrode 150 and the second upper electrode 152. The plate electrode may include, e.g., silicon-germanium doped with impurities.

As described above, the first upper electrode 150 formed on the dielectric layer 140 may have the metal nitride further including the first material having a work function of 4.8 eV or more. Therefore, the first upper electrode 150 may have the work function higher than a work function of an upper electrode including only the metal nitride. Additionally, the first upper electrode 150 may continuously formed to cover the upper surface of the dielectric layer 140. Accordingly, leakage currents of the capacitor including the first upper electrode 150 may be reduced.

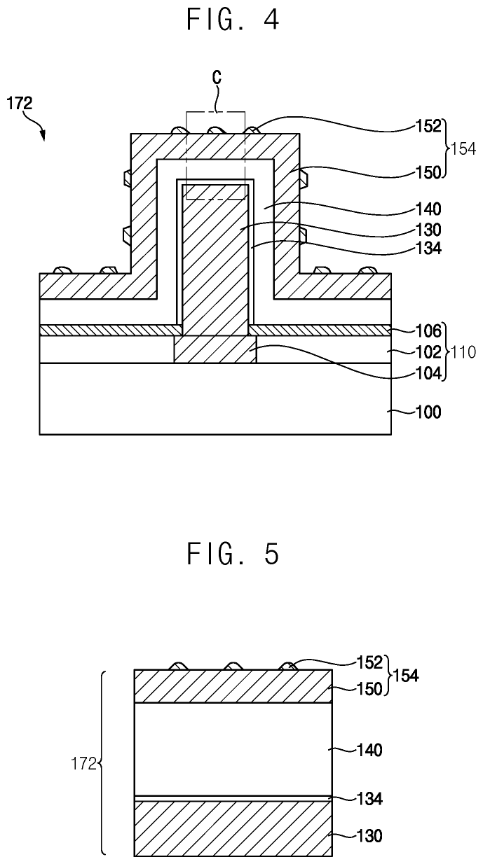

FIG. 4 is a cross-sectional view illustrating a capacitor according to example embodiments. FIG. 5 is an enlarged cross-sectional view illustrating the capacitor shown in FIG. 4 according to example embodiments.

FIG. 4 is a vertical cross-sectional view of the capacitor having a lower electrode of pillar shape. FIG. 5 is the enlarged cross-sectional view of portion C of FIG. 4.

The capacitor shown in FIGS. 4 and 5 is the same as the capacitor shown in FIGS. 1 and 2, except that the capacitor may further include an interface layer pattern.

Referring to FIGS. 4 and 5, the capacitor 172 may include the lower electrode 130, an interface layer pattern 134, the dielectric layer 140, and the upper electrode 154. The upper electrode 154 includes the first upper electrode 150 and the second upper electrode 152.

The interface layer pattern 134 may be formed only on a surface of the lower electrode 130. When a plurality of lower electrodes 130 are formed, the interface layer pattern 134 may not be formed on a region between the lower electrodes 130. For example, the interface layer pattern 134 may not be formed on the etch stop layer 106 between the lower electrodes 130. The interface layer pattern 134 may include a metal oxide doped with a pentavalent element or a metal nitride doped with a pentavalent element. The pentavalent element may include, e.g., V, Nb and Ta, etc. For example, the interface layer pattern 134 may include titanium oxide containing a pentavalent element or titanium nitride containing a pentavalent element. The interface layer pattern 134 may contact the dielectric layer 140. When the interface layer pattern 134 is further included in the capacitor, a capacitance of the capacitor may increase.

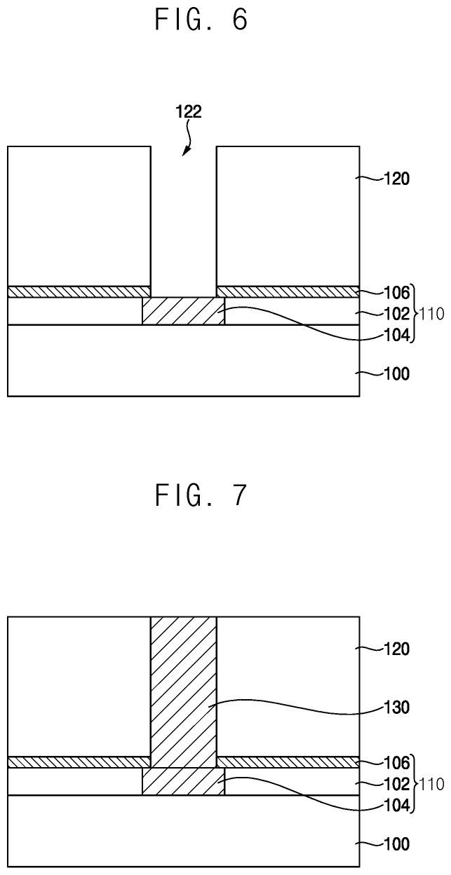

FIGS. 6 to 12 are cross-sectional views illustrating a method for forming a capacitor according to example embodiments.

Referring to FIG. 6, a lower structure 110 may be formed on a substrate 100.

The lower structure 110 may include a transistor, a contact plug, a conductive pattern 104, a conductive line, an insulating interlayer 102, and an etch stop layer 106, etc.

A mold layer 120 may be formed on the lower structure 110. Portions of the mold layer 120 and the etch stop layer 106 may be etched to form a hole 122 for forming a lower electrode of a capacitor. Although only one hole is shown in FIG. 6, the number of the holes may not be limited thereto. A plurality of holes may be repeatedly arranged on the lower structure 110.

An upper surface of the conductive pattern 104 may be exposed on a bottom of the hole 122.

Referring to FIG. 7, a lower electrode layer may be formed on the mold layer 120 to fill the hole 122. The lower electrode layer may be planarized until an upper surface of the mold layer 120 is exposed to form a lower electrode 130 filling the hole 122.

In example embodiments, the lower electrode layer may be deposited by a deposition process, e.g., a chemical vapor deposition (CVD) or atomic layer deposition (ALD) process. The planarization process may include, e.g., a chemical mechanical polishing process and/or an etch-back process.

In some example embodiments, the lower electrode layer may be formed on the lower structure 110, and then the lower electrode layer may be patterned by a photolithography process to form the lower electrode 130. In this case, the mold layer 120 may not be formed.

The lower electrode layer may be formed of or include metal or metal nitride. In example embodiments, the lower electrode layer may include, e.g., titanium nitride (TiN), titanium (Ti), tantalum (Ta), or tantalum nitride (TaN).

In example embodiments, the lower electrode layer may be formed by the deposition process using a metal source gas such as titanium source gas and a nitrogen source gas such as ammonia (NH₃). Accordingly, the lower electrode layer may include, e.g., the metal nitride such as titanium nitride.

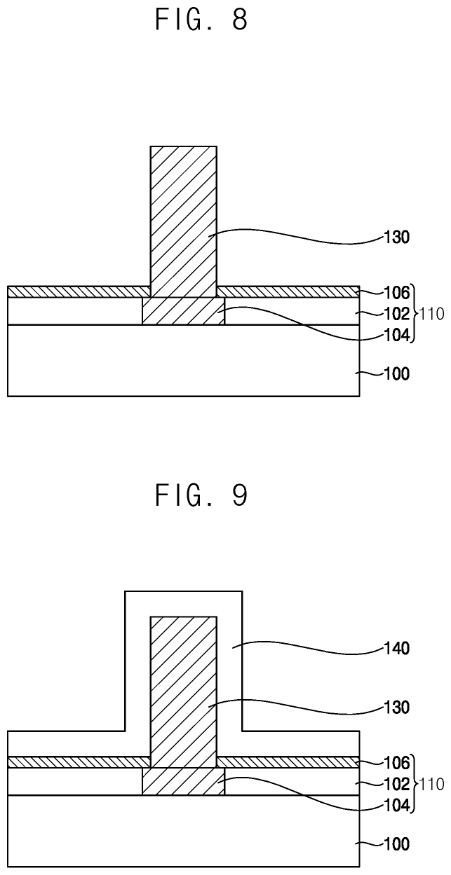

Referring to FIG. 8, the mold layer 120 may be removed so that a sidewall and an upper surface of the lower electrode 130 having a pillar shape may be exposed.

In example embodiments, the mold layer 120 may be removed by a wet etching process.

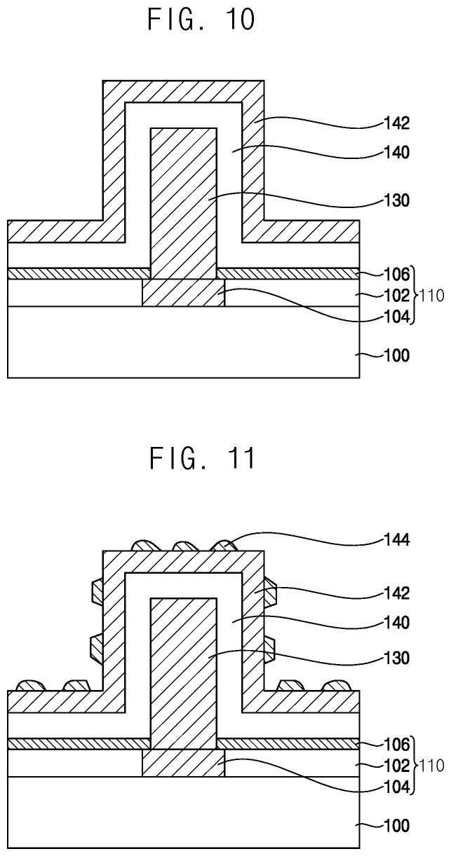

Referring to FIG. 9, a dielectric layer 140 may be conformally formed on the sidewall and upper surface of the lower electrode 130 and on the etch stop layer 106.

The dielectric layer 140 may include a metal oxide. In example embodiments, the dielectric layer 140 may include, e.g., hafnium oxide, zirconium oxide, or aluminum oxide.

In example embodiments, a thickness of the dielectric layer 140 may be about 30 Å to about 60 Å.

In example embodiments, the dielectric layer 140 may be formed by an atomic layer deposition process.

In some example embodiments, before forming the dielectric layer 140, an interface layer pattern (referred to FIG. 4, 134) may be further formed on the sidewall and upper surface of the lower electrode 130. In this case, a capacitor shown in FIGS. 4 and 5 may be formed by subsequent processes.

In more detail, a preliminary interfacial layer may be formed on the sidewall and upper surface of the lower electrode 130 and on the etch stop layer 106, and portions of the preliminary interfacial layer may be removed to only remain the preliminary interfacial layer positioned on the sidewall and upper surface of the lower electrode 130. Therefore, the interface layer pattern 134 may be formed on the sidewall and upper surface of the lower electrode 130. The preliminary interface layer may be formed by forming a layer doped with the pentavalent element and heat-treating of the layer doped with the pentavalent element. Accordingly, the preliminary interfacial layer positioned on the sidewall and upper surface of the lower electrode 130 may be reacted with the lower electrode 130, so that the preliminary interfacial layer positioned on the sidewall and upper surface of the lower electrode 130 may include a metal included in the lower electrode 130. However, the preliminary interfacial layer positioned on the etch stop layer 106 may not include the metal included in the lower electrode 130. Accordingly, the preliminary interface layer positioned on the etch stop layer 106 may be selectively removed, and thus the interface layer pattern 134 may be formed on the sidewall and upper surface of the lower electrode 130.

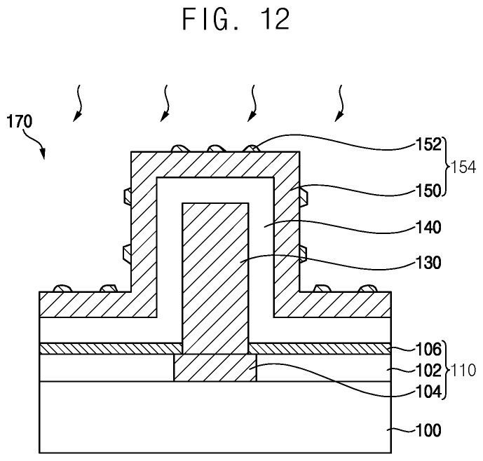

Referring to FIG. 10, a preliminary metal nitride layer 142 may be formed on the dielectric layer 140.

The preliminary metal nitride layer 142 may be continuously formed on the surface of the dielectric layer 140 by a deposition process, e.g., an atomic layer deposition process or a chemical vapor deposition process. The preliminary metal nitride layer 142 may cover the surface of the dielectric layer 140. The preliminary metal nitride layer 142 may be formed conformally along a surface profile of the dielectric layer 140.

In example embodiments, the preliminary metal nitride layer 142 may include, e.g., TiN, TiSiN, TaN, TaSiN, NbN, or NbSiN.

For example, the preliminary metal nitride layer 142 may be formed by the deposition process using a metal source gas such as titanium and a nitrogen source gas such as ammonia (NH₃). Accordingly, the preliminary metal nitride layer 142 may be formed of titanium nitride.

The preliminary metal nitride layer 142 may have a thickness of about 20 Å to about 50 Å. When the thickness of the preliminary metal nitride layer 142 is less than 20 Å, the preliminary metal nitride layer may not be continuously deposited on the dielectric layer 140. When the thickness of the preliminary metal nitride layer 142 is greater than 50 Å, a first material may not be sufficiently diffused into the preliminary metal nitride layer 142 in subsequent processes.

Referring to FIG. 11, a preliminary conductive layer 144 including a first material having a work function higher than a work function of the preliminary metal nitride layer 142 may be formed on the preliminary metal nitride layer 142.

In example embodiments, the first material may have the work function of 4.8 eV or more. The preliminary conductive layer 144 may have a work function of 4.8 eV or more. The first material may be formed of or include metal.

In example embodiments, the first material may be formed of or include, e.g., Ni, Pd, Ir or Pt.

In example embodiments, the preliminary conductive layer 144 may include one first material or two or more first materials. For example, the Ni layer and the Pd layer may be sequentially formed on the preliminary metal nitride layer 142 to form the preliminary conductive layer 144 including the Ni layer and the Pd layer. For other example, the Ir layer and the Pt layer may be sequentially formed on the preliminary metal nitride layer 142 to form the preliminary conductive layer 144 including the Ir layer and the Pt layer.

The preliminary conductive layer 144 may be formed by an atomic layer deposition process or a chemical vapor deposition process.

The preliminary conductive layer 144 may be discontinuously formed on the preliminary metal nitride layer 142. The preliminary conductive layer 144 may have a shape in which the first materials are disposed on the upper surface of the preliminary metal nitride layer 142 to be spaced apart from each other. The preliminary conductive layer 144 may collectively refer to a plurality of first materials having an isolated island shape arranged to be spaced apart from each other on the preliminary metal nitride layer 142. Accordingly, the preliminary conductive layer 144 may not cover an entire upper surface of the preliminary metal nitride layer 142, but may partially cover the upper surface of the preliminary metal nitride layer 142.

In example embodiments, the preliminary conductive layer 144 may be formed to have a thickness less than the thickness of the preliminary metal nitride layer 142. For example, the preliminary conductive layer 144 may be formed to have the thickness of about 5 Å to about 30 Å. The preliminary conductive layer 144 may serve as a layer for diffusing the first material through subsequent processes. Therefore, when the thickness of the preliminary conductive layer 144 is less than 5 Å, an amount of the first material for diffusing may be small. When the thickness of the preliminary conductive layer 144 is greater than 30 Å, a reliability failure of the capacitor may occur due to non-uniformity of the upper surface of the preliminary conductive layer 144.

Referring to FIG. 12, a heat treatment process may be performed on the preliminary conductive layer 144 to diffuse the first material included in the preliminary conductive layer 144 downward. The first material may be diffused into the preliminary metal nitride layer 142.

Accordingly, the preliminary metal nitride layer 142 may further include the first material therein, so that the preliminary metal nitride layer 142 may be converted into a first upper electrode 150. In example embodiments, the first upper electrode 150 may include, e.g., TiN, TiSiN, TaN, TaSiN, NbN, or NbSiN with the first material included therein. In example embodiments, the first upper electrode 150 may be formed of TiN, TiSiN, TaN, TaSiN, NbN, or NbSiN with the first material included therein. For example, the first upper electrode 150 may include TiN further including the first material or TiSiN further including the first material. For example, the first upper electrode 150 may be formed of TiN and the first material or TiSiN and the first material.

After performing the heat treatment process, some first material may remain on the first upper electrode 150 without diffusing, and remaining first material may be referred to as a second upper electrode 152. A thickness of the second upper electrode 152 may be less the thickness of the preliminary conductive layer 144. The first and second upper electrodes 150 and 152 may serve as an upper electrode 154 of the capacitor.

The second upper electrode 152 may have a shape in which the first materials are spaced apart from each other. The second upper electrode 152 may collectively refer to a plurality of first materials having an isolated island shape arranged to be spaced apart from each other on the first upper electrode 150. Accordingly, the second upper electrode 152 may not cover an entire of an upper surface of the first upper electrode 150, but may partially cover the upper surface of the first upper electrode 150.

In example embodiments, the heat treatment process may be performed at a temperature of about 300° C. to about 600° C. When the temperature of the heat treatment is lower than 300° C., the first material may not be sufficiently diffused. When the temperature of the heat treatment is higher than 600° C., a thermal budget may occur.

In example embodiments, a concentration of the first material included in the first upper electrode 150 may decrease from the upper surface of the first upper electrode 150 to a bottom of the first upper electrode 150.

A plate electrode may be further formed on the first upper electrode 150 and the second upper electrode 152. For example, the plate electrode may include, e.g., silicon-germanium doped with impurities.

The capacitor 170 including the lower electrode 130, the dielectric layer 140, the first upper electrode 150 and the second upper electrode 152 may be formed by the above processes. As the first upper electrode 150 is formed of the metal nitride further including the first material, the first upper electrode 150 may have the work function higher than the work function of the preliminary metal nitride layer 142 including only of the metal nitride. As the first upper electrode 150 has a high work function, the leakage currents of the capacitor may be decreased.

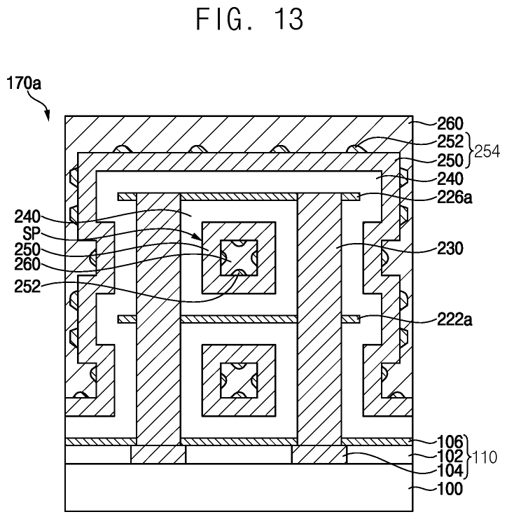

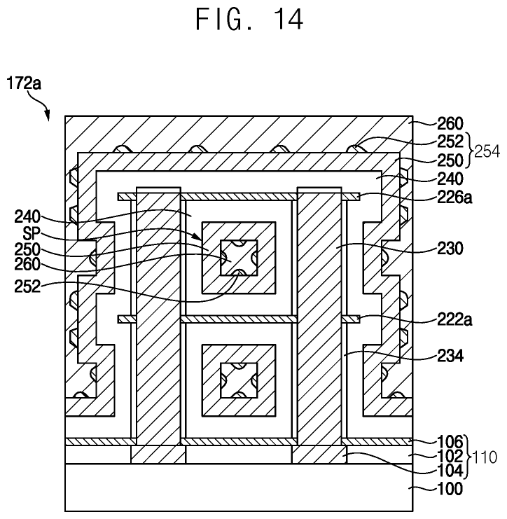

FIG. 13 is a cross-sectional view illustrating capacitors according to example embodiments.

With reference to FIG. 13, a plurality of regularly arranged capacitors may be described. Each of capacitors shown in FIG. 13 may be the same as the capacitor shown in FIG. 1, except that each of the capacitors may further include a support layer pattern and a plate electrode. Therefore, repeated explanations may be omitted.

Referring to FIG. 13, a capacitor 170a may include a lower electrode 230, a first support layer pattern 222a, a second support layer pattern 226a, a dielectric layer 240, a first upper electrode 250, and a second upper electrode 252. In addition, a plate electrode 260 may be formed on the second upper electrode 252 and the first upper electrode 250.

In example embodiments, the capacitor 170a may be disposed on the lower structure 110 formed on the substrate 100. The lower structure 110 may include, e.g., a transistor, a contact plug, a conductive pattern 104, a conductive line, an insulating interlayer 102, and an etch stop layer 106, etc.

In example embodiments, the lower electrode 230 may have a pillar shape. Alternatively, the lower electrode may have a cylindrical shape.

The plurality of lower electrodes 230 may be regularly and repeatedly arranged. In example embodiments, the lower electrodes 230 may have a honeycomb arrangement in which the lower electrodes 230 are respectively disposed at vertices and center portions of connected hexagons.

The first support layer pattern 222a may have a structure connected while surrounding a sidewall of each lower electrode 230. The second support layer pattern 226a may have a structure connected while surrounding the sidewall of each lower electrode 230. For example, each of the first and second support layer patterns 222a and 226a may have an upper surface and a lower surface in a horizontal direction parallel to the upper surface of the substrate 100. The first and second support layer patterns 222a and 226a may be disposed at different vertical levels. The lower electrodes 230 may be supported by the first and second support layer patterns 222a and 226a, so that the lower electrodes 230 may not lean. In the FIG. 13, two support layer patterns may be formed on the sidewall of the lower electrode 230. However, the number of the support layer patterns may not be limited thereto. One support layer pattern or three or more support layer patterns may be formed on the sidewall of the lower electrode 230.

The first support layer pattern 222a may surround a central sidewall of the lower electrode 230, and the second support layer pattern 226a may surround an upper sidewall of the lower electrode 230. In a plan view, each of the first and second support layer patterns 222a and 226a may have a mesh shape.

The first and second support layer patterns 222a and 226a may include an insulating nitride material such as silicon nitride (SiN), boronitride (SiBN), or silicon carbonitride (SiCN).

The dielectric layer 240 may be formed on the lower electrode 230 and the first and second support layer patterns 222a and 226a. The first upper electrode 250 may be formed on the dielectric layer 240. The first upper electrode 250 may cover a surface of the dielectric layer 240. The first upper electrode 250 may be continuously formed on the surface of the dielectric layer 240. A space SP and a portion of the dielectric layer 240 may be formed between the lower electrodes 230. For example, in the cross-sectional view, the space SP may have a rectangular shape between the lower electrodes 230. The space SP may contact the portion of the dielectric layer 240 between the lower electrodes 230. The first upper electrode 250 may not completely fill the space SP between the lower electrodes 230. For example, the first upper electrode 250 may partially fill the space SP. The first upper electrode 250 may be conformally formed along a surface profile of the dielectric layer 240.

In example embodiments, the first upper electrode 250 may include a metal nitride further including a first material having a work function higher than a work function of the metal nitride. In example embodiments, the first upper electrode 250 may be formed of a metal nitride and a first material having a work function higher than a work function of the metal nitride. The first material may have the work function of 4.8 eV or more.

In example embodiments, the metal nitride may include, e.g., TiN, TiSiN, TaN, TaSiN, NbN, or NbSiN. For example, the metal nitride may include titanium nitride, and the first material may include a material having the work function higher than a work function of the titanium nitride.

In example embodiments, the first material may include, e.g., Ni, Pd, Ir, or Pt. In example embodiments, the first material may include one metal or two or more metal.

For example, the first upper electrode 250 may include titanium nitride (TiN) including Ni, Pd, Ir or Pt, or titanium silicon nitride (TiSiN) including Ni, Pd, Ir or Pt. For example, the first upper electrode 250 may be formed of titanium nitride (TiN) and Ni, Pd, Ir or Pt, or titanium silicon nitride (TiSiN) and Ni, Pd, Ir or Pt.

A concentration of the first material of the first upper electrode 250 may decrease in a direction from an upper surface of the first upper electrode 250 toward the dielectric layer 240. The first material may not be included in the dielectric layer 240.

The second upper electrode 252 including the first material may be formed on the first upper electrode 250. The second upper electrode 252 may be discontinuously disposed on the first upper electrode 250, so that the second upper electrode 252 may not cover an entire surface of the first upper electrode 250. The second upper electrode 252 may partially cover the surface of the first upper electrode 250. The second upper electrode 252 may include the first material the same as the first material included in the first upper electrode 250. The second upper electrode 252 may have a thickness less than the thickness of the first upper electrode 250. The second upper electrode 252 may not completely fill the space SP between the lower electrodes 230. The first upper electrode 250 and the second upper electrode 252 may not completely fill the space SP between the lower electrodes 230. For example, the first upper electrode 250 and the second upper electrode 252 may partially fill the space SP between the lower electrodes 230.

The plate electrode 260 may be formed on the first and second upper electrodes 250 and 252, and the plate electrode 260 may completely fill the space SP with the first and second upper electrodes 250 and 252 between the lower electrodes 230. An upper surface of the plate electrode 260 may be higher than an uppermost surface of the lower electrode 230. For example, the plate electrode 260 may include, e.g., silicon-germanium doped with impurities.

FIG. 14 is a cross-sectional view illustrating a capacitor according to example embodiments.

A capacitor 172a shown in FIG. 14 may be the same as the capacitor 170a described with reference to FIG. 13, except that the capacitor may further include an interface layer pattern.

Referring to FIG. 14, the capacitor 172a may include the lower electrode 230, an interface layer pattern 234, the first support layer pattern 222a, the second support layer pattern 226a, the dielectric layer 240, the first upper electrode 250 and the second upper electrode 252. In addition, the plate electrode 260 may be formed on the second upper electrode 252 and the first upper electrode 250.

The interface layer pattern 234 may be formed only on a surface of the lower electrode 230. Accordingly, the interface layer pattern 234 may not be formed on the etch stop layer 106, the first support layer pattern 222a and the second support layer pattern 226a. The interface layer pattern 234 may be the same as the interface layer pattern 134 described with reference to FIGS. 4 and 5.

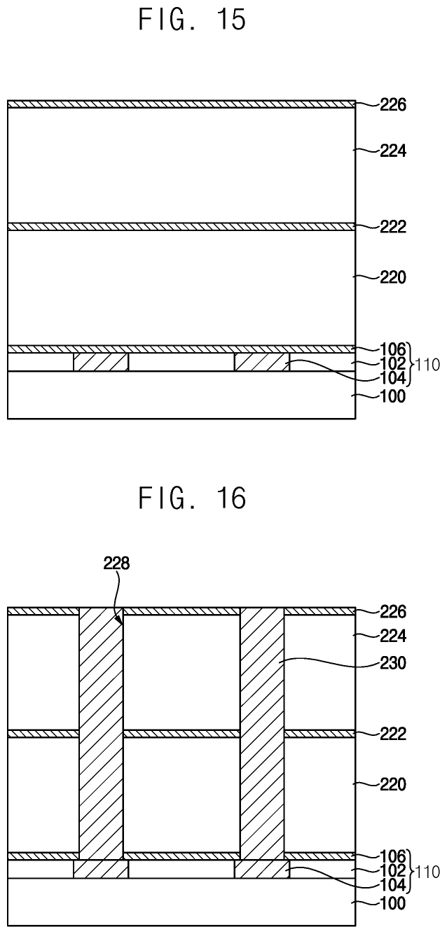

FIGS. 15 to 23 are cross-sectional views illustrating a method for forming a capacitor according to example embodiments.

Referring to FIG. 15, the lower structure 110 may be formed on the substrate 100.

The lower structure 110 may include, e.g., a transistor, a contact plug, a conductive pattern 104, a conductive line, an insulating interlayer 102, and an etch stop layer 106.

Mold layers 220 and 224 and support layers 222 and 226 may be alternately formed on the lower structure 110. In example embodiments, a first mold layer 220, a first support layer 222, a second mold layer 224, and a second support layer 226 may be sequentially formed on the lower structure 110. Hereinafter, two support layers and two mold layers formed on the lower structure 110 may be described, but the number of the support layers and the mold layers may not be limited thereto. One or three or more support layers and mold layers may be formed on the lower structure 110.

Referring to FIG. 16, the second support layer 226, the second mold layer 224, the first support layer 222, the first mold layer 220, and the etch stop layer 106 may be etched to form holes 228 for forming lower electrodes of capacitors. An upper surface of the conductive pattern 104 may be exposed by a bottom of each of the holes 228.

A lower electrode layer may be formed on the second support layer 226 to fill the holes 228. The lower electrode layer may be planarized until an upper surface of the second support layer 226 is exposed to form a lower electrode 230 in each of the holes 228. The process for forming the lower electrodes 230 may be the same as the processes described with reference to FIGS. 6 and 7.

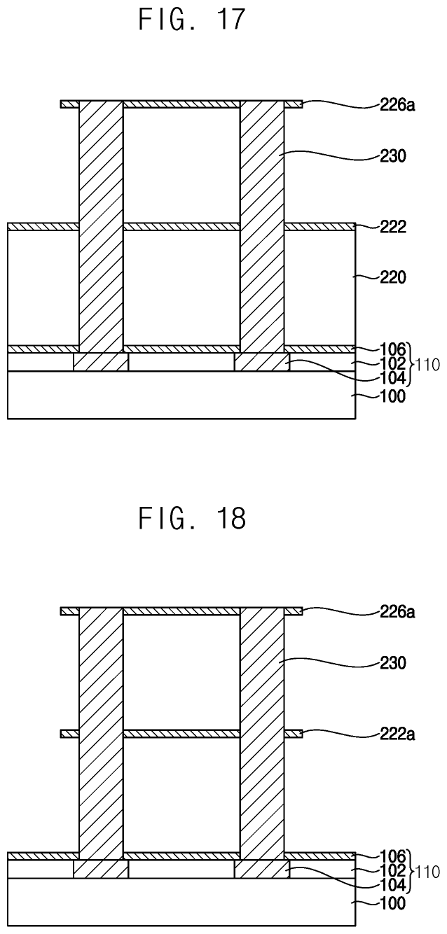

Referring to FIG. 17, a portion of the second support layer 226 may be etched to form a second support layer pattern 226a. The second mold layer 224 may be removed after forming the second support layer pattern 226a. The removing process may include a wet etching process. When the second mold layer 224 is removed, the first support layer 222 may be exposed.

Referring to FIG. 18, a portion of the first support layer 222 may be etched to form a first support layer pattern 222a. The first mold layer 220 may be removed after forming the first support layer pattern 222a. The removing process may include a wet etching process. Accordingly, the surfaces of the lower electrodes 230 may be exposed.

Referring to FIG. 19, a dielectric layer 240 may be formed on a sidewall and an upper surface of the lower electrode 230 and on the etch stop layer 106 and the first and second support layer patterns 222a and 226a. The spaces SP may be formed between the lower electrodes 230. The process for forming the dielectric layer 240 may be the same as the processes described with reference to FIG. 9.

In some example embodiments, before forming the dielectric layer 240, an interface layer pattern 234 may be further formed on the sidewall and upper surface of the lower electrode 230. In this case, the capacitor described with reference to FIG. 14 may be formed by subsequent processes.

Particularly, a preliminary interface layer may be conformally formed on the sidewall and upper surface of the lower electrode 230, the first and second support layer patterns 222a and 226a and the etch stop layer 106. A portion of the preliminary interface layer may be removed so that the preliminary interface layer remains only on the sidewall and upper surface of the lower electrode 230. Therefore, the interface layer pattern 234 may be formed on the sidewall and upper surface of the lower electrode 230. The interface layer pattern 234 may not be formed on the etch stop layer 106 and the first and second support layer patterns 222a and 226a.

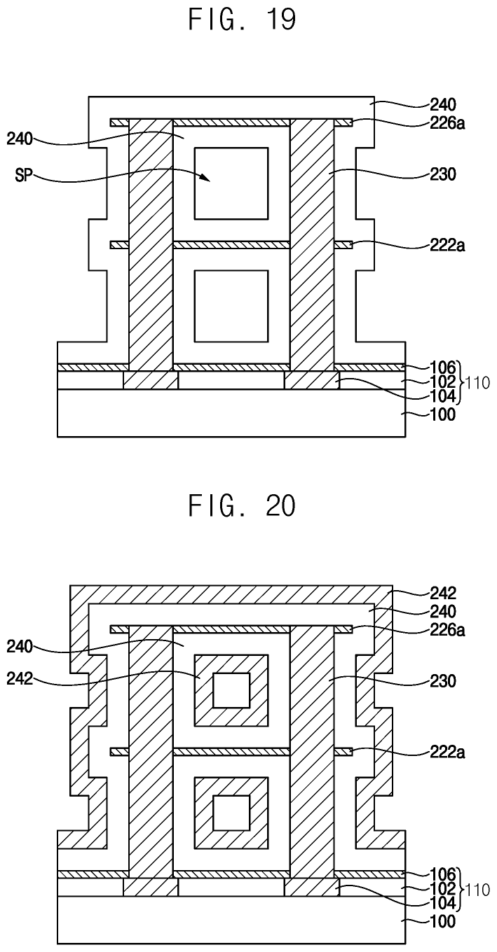

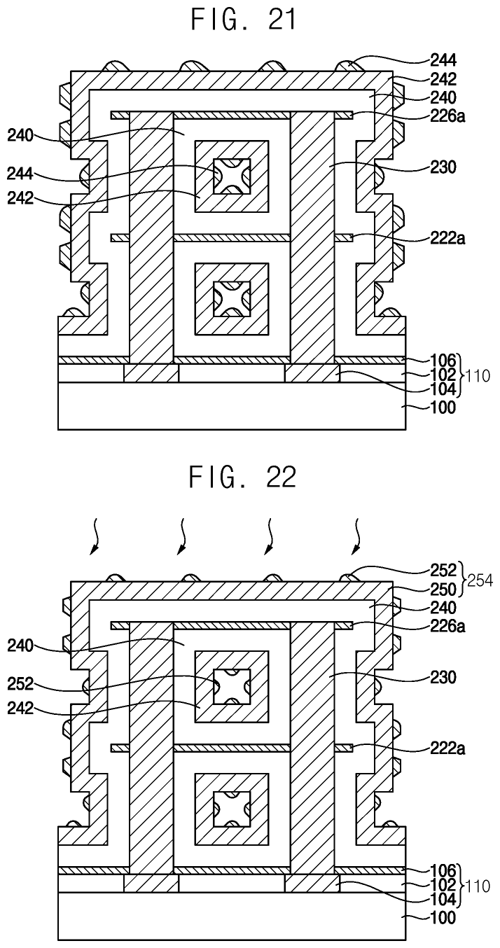

Referring to FIG. 20, a preliminary metal nitride layer 242 may be formed on the dielectric layer 240. The preliminary metal nitride layer 242 may be conformally formed along a surface profile of the dielectric layer 240.

If the preliminary metal nitride layer 242 completely fills the space SP between the lower electrodes 230, the first material may not be uniformly diffused into the preliminary metal nitride layer 242 formed in the space SP between the lower electrodes 230, in subsequent processes. Therefore, the preliminary metal nitride layer 242 may be formed so as not to completely fill the space SP between the lower electrodes 230.

The process for forming the preliminary metal nitride layer 242 may be the same as the processes described with reference to FIG. 10.

Referring to FIG. 21, a preliminary conductive layer 244 may be formed on the preliminary metal nitride layer 242. The preliminary conductive layer 244 may be formed of or include a first material having a work function higher than a work function of the preliminary metal nitride layer 242.

The preliminary conductive layer 244 may be discontinuously formed on a surface of the preliminary metal nitride layer 242.

If the preliminary conductive layer 244 completely fills the space SP between the lower electrodes 230, the first material may not be uniformly diffused into the preliminary metal nitride layer 242 formed in the space SP between the lower electrodes 230, in subsequent processes. Therefore, the preliminary conductive layer 244 may be formed so as not to completely fill the space SP between the lower electrodes 230.

The process for forming the preliminary conductive layer 244 may be the same as the processes described with reference to FIG. 11.

Referring to FIG. 22, a heat treatment process may be performed on the preliminary conductive layer 244, so that the first material of the preliminary conductive layer 244 may be diffused downward. The first material may be diffused into the preliminary metal nitride layer 242, and thus the preliminary metal nitride layer 242 may be converted into a first upper electrode 250 including the first material. After performing the heat treatment process, some first material may remain on the first upper electrode 250, which may be referred to as the second upper electrode 252. The first upper electrode 250 and the second upper electrode 252 may serve as an upper electrode 254 of the capacitor.

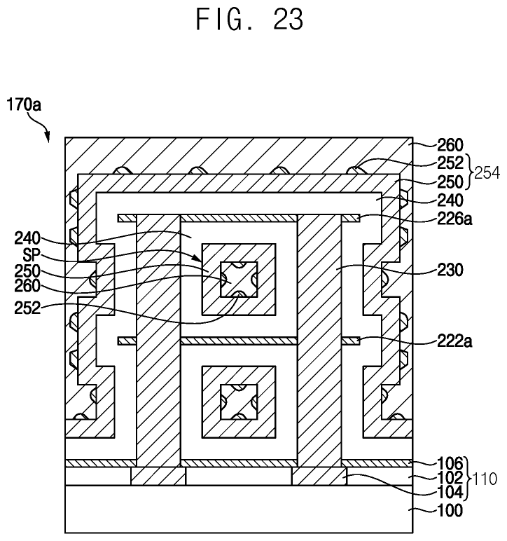

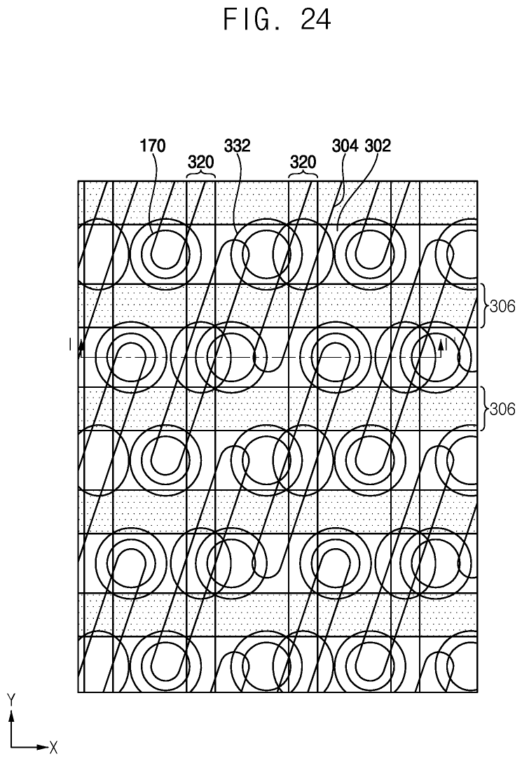

Referring to FIG. 23, a plate electrode 260 may be formed on the upper electrode 254 to completely fill the space SP with the first and second upper electrodes 250 and 252 between the lower electrodes 230. An upper surface of the plate electrode 260 may be higher than the uppermost surface of the lower electrode 230. For example, the plate electrode 260 may include, e.g., silicon-germanium doped with impurities. The plate electrode 260 may be formed by a chemical vapor deposition process or an atomic layer deposition process.

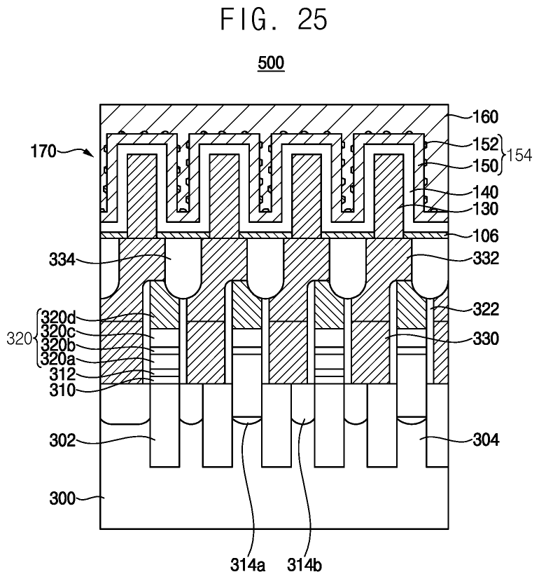

FIG. 24 is a plan view illustrating a layout of a semiconductor device according to example embodiments. FIG. 25 is a cross-sectional view of a semiconductor device according to example embodiments.

The semiconductor device may be a dynamic random access memory (DRAM) device. To avoid drawing complexity, structures on a lower electrode of a capacitor may not be shown in FIG. 24. FIG. 25 is a cross-sectional view taken along line I-I′ of FIG. 24.

Referring to FIGS. 24 and 25, a DRAM device 500 may be formed on a substrate 300.

The DRAM device 500 may include selection transistors, capacitors 170 and bit line structures 320. A unit memory cell of the DRAM device 500 may include one selection transistor and one capacitor 170. For example, the one selection transistor may be a cell transistor of the DRAM device 500.

The substrate 300 may include a device isolation layer 302. An upper portion of the substrate 300 between the device isolation layers 302 may be defined as an active region 304.

The substrate 300 may include a gate trench extending in a first direction X parallel to an upper surface of the substrate 300. A gate structure 306 may be formed in the gate trench.

In example embodiments, the gate structure 306 may include a gate insulation layer, a gate electrode, and a capping insulation pattern. The gate structure 306 may extend in the first direction X. A plurality of gate structures 306 may be arranged in a second direction Y parallel to the surface of the substrate 300 and perpendicular to the first direction X.

First and second impurity regions 314a and 314b serving as source/drain regions may be formed at the active region 304 between the gate structures 306. The gate structure 306 and the first and second impurity regions 314a and 314b may serve as the selection transistor.

A first insulation pattern 310 and a second insulation pattern 312 may be stacked on the active region 304, the device isolation layer 302 and the gate structure 306. For example, the first insulation pattern 310 may include an oxide such as silicon oxide, and the second insulation pattern 312 may include a nitride such as silicon nitride.

A recess may be included at a portion of the substrate 300 where the first and second insulation patterns 310 and 312 are not formed. An upper surface of the first impurity region 314a may be exposed on a bottom of the recess.

The bit line structure 320 may be formed on the second insulation pattern 312 and the recess. The bit line structure 320 may include a conductive pattern 320a, a barrier metal pattern 320b, a metal pattern 320c and a hard mask pattern 320d. For example, the conductive pattern 320a may include polysilicon doped with impurities. The bit line structure 320 may extend in the second direction Y. A plurality of the bit lines may be arranged in the first direction X. In example embodiments, a spacer 322 may be formed on a sidewall of the bit line structure 320. A plurality of spacers 322 may be laterally stacked on the sidewall of the bit line structure 320.

A first insulating interlayer (not shown) may fill a space between the bit line structures 320.

A stacked structure including a contact plug 330 and a landing pad 332 may pass through the first insulating interlayer, the second insulation pattern 312 and the first insulation pattern 310, and the stacked structure may contact the second impurity region 314b. For example, the contact plug 330 may contact the second impurity region 314b. The contact plug 330 may be disposed between the bit line structures 320. The landing pad 332 may be formed on the contact plug 330 and the bit line structure 320. For example, the landing pad 332 may be formed on the hard mask pattern 320d of the bit line structure 320. An insulation pattern 334 may be formed between the landing pads 332.

The etch stop layer 106 may be formed on the landing pad 332, the insulation pattern 334, and the first insulating interlayer. The capacitor 170 may pass through the etch stop layer 106, and may contact the landing pad 332.

The etch stop layer 106 may include, e.g., silicon nitride, silicon oxynitride, etc.

In example embodiments, the etch stop layer 106, the device isolation layer 302, the active region 304, the gate structure 306, the first insulation pattern 310, the second insulation pattern 312, the bit line structure 320, the spacer 322, the contact plug 330, and the landing pad 332 of FIG. 25 may correspond to the lower structure 110 of FIG. 1, FIG. 4, FIG. 13, or FIG. 14.

The capacitor 170 includes the lower electrode 130, the dielectric layer 140, the first upper electrode 150, and the second upper electrode 152. A bottom of the lower electrode 130 may contact the landing pad 332. The first upper electrode 150 may cover the dielectric layer 140. The second upper electrode 152 may be discontinuously formed on the first upper electrode 150 to partially cover the first upper electrode 150. The plate electrode 160 may be formed on the second upper electrode 152 and the first upper electrode 150.

In example embodiments, the capacitor 170 of the DRAM device 500 may be substantially the same as the capacitor described in FIG. 1. In some example embodiments, the capacitor 170 of the DRAM device 500 may be substantially the same as the capacitor illustrated in FIG. 4, FIG. 13, or FIG. 14.

Leakage currents of the capacitor formed of the second upper electrode 152 may be decreased.

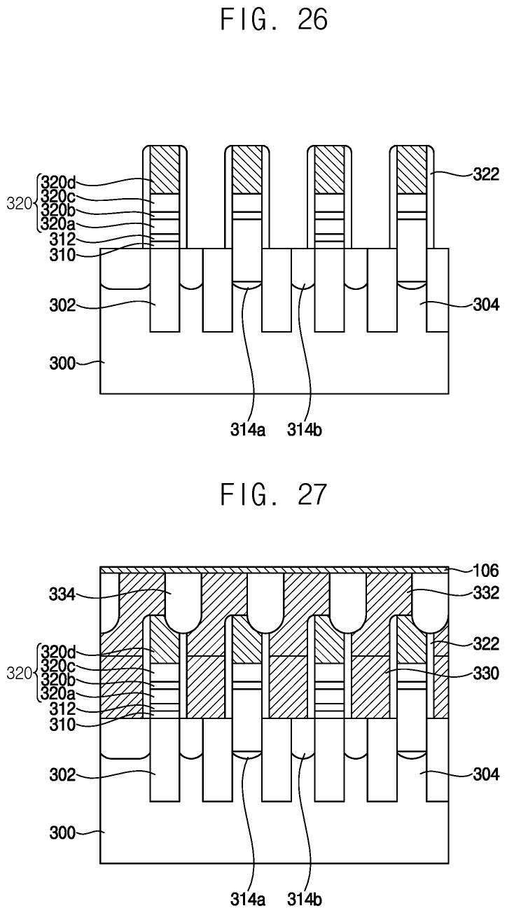

FIGS. 26 and 27 are cross-sectional views illustrating a method for manufacturing a semiconductor device according to example embodiments.

Referring to FIG. 26, a shallow trench isolation (STI) process may be performed on the substrate 300 to form a device isolation layer 302. Accordingly, the substrate 300 may be divided into a device isolation region where the device isolation layer 302 is formed, and an active region 304 between the device isolation layers 302.

Upper portions of the substrate 300 and the device isolation layer 302 may be etched to form a gate trench extending in the first direction X. A gate structure may be formed in the gate trench. First and second impurity regions 314a and 314b may be formed at the active region adjacent to both sides of the gate structure.

A first insulation pattern 310 and a second insulation pattern 312 may be formed on the active region, the device isolation layer 302 and the gate structure. A recess may be formed on the substrate 300 where the first and second insulation patterns 310 and 312 are not formed. An upper surface of the first impurity region 314a may be exposed on a bottom of the recess.

A bit line structure 320 extending in the second direction Y may be formed on the second insulation pattern 312 and the recess. The bit line structure 320 may include a conductive pattern 320a, a barrier metal pattern 320b, a metal pattern 320c and a hard mask pattern 320d stacked. In example embodiments, a spacer 322 may be formed on a sidewall of the bit line structure 320.

Referring to FIG. 27, a first insulating interlayer may be formed to cover the bit line structures 320.

A portion of the first insulating interlayer between the bit line structures 320 may be etched to form a contact hole exposing the second impurity region 314b of the substrate 300. A stacked structure including a contact plug 330 and a landing pad 332 may be formed to fill the contact hole. An insulation pattern 334 may be formed between the landing pads 332.

The etch stop layer 106 may be formed on the first insulating interlayer, the landing pad 332, and the insulation pattern 334.

Referring to FIG. 25 again, processes that are substantially the same or similar to the processes described with reference to FIGS. 6 to 12 may be performed to form the capacitor 170. The capacitor 170 may include the lower electrode 130, the dielectric layer 140, the first upper electrode 150, and the second upper electrode 152. The plate electrode 160 may be formed on the first and second upper electrodes 150 and 152.

In some example embodiments, processes substantially the same as or similar to those described with reference to FIGS. 15 to 23 may be performed to form the capacitor shown in FIG. 13.

Accordingly, a DRAM device including the capacitor with low leakage currents may be manufactured.

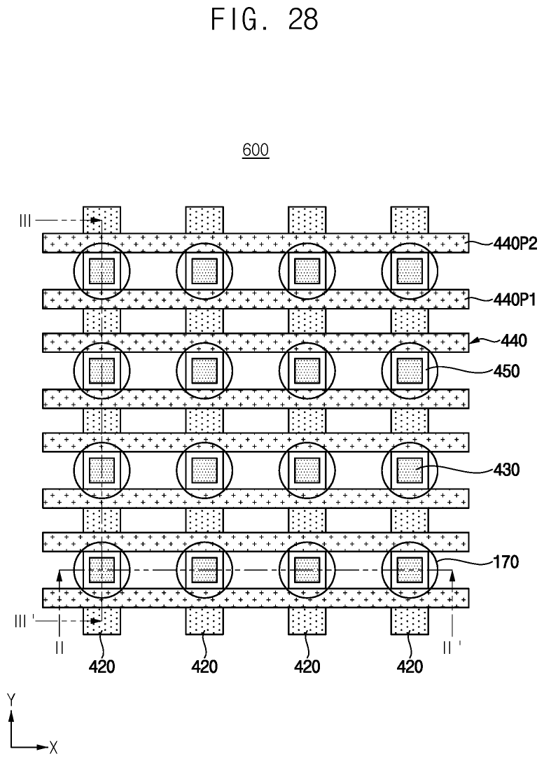

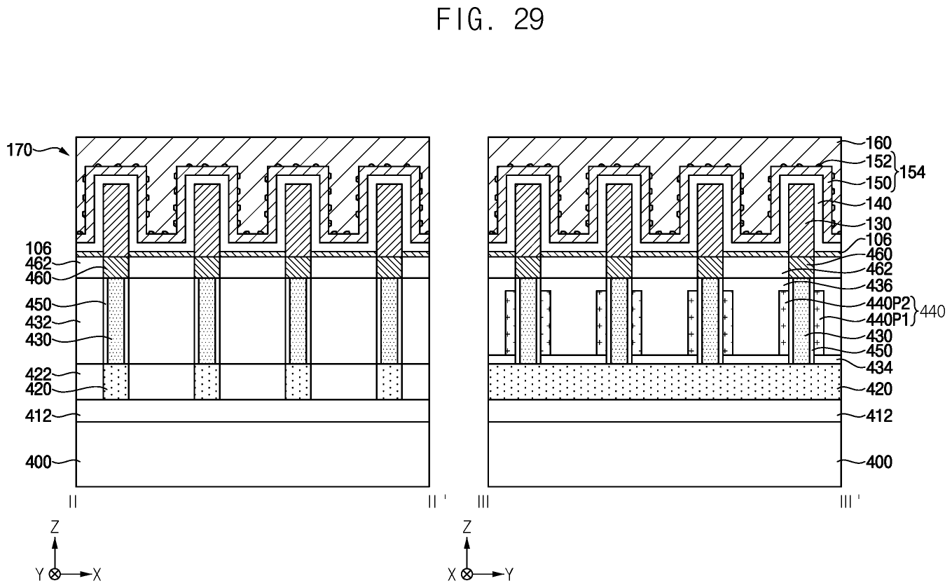

FIG. 28 is a layout illustrating a semiconductor device according to example embodiments. FIG. 29 is a cross-sectional view illustrating a semiconductor device according to example embodiments.

FIG. 29 includes a cross-sectional view taken along lines II-II′ and III-III′ of FIG. 28. The semiconductor device is a DRAM device having a vertical channel transistor (VCT) and the capacitor described with reference to FIGS. 1 and 2. Redundant description of the capacitor may be omitted.

Referring to FIGS. 28 and 29, a DRAM device 600 may include a substrate 400, a plurality of first conductive lines 420, a channel layer 430, a gate electrode 440, a gate insulation layer 450, and the capacitor 170. The DRAM device 600 may include a vertical channel transistor (VCT). The vertical channel transistor may have a structure in which a channel length of the channel layer 430 extends in a vertical direction Z from an upper surface of the substrate 400.

A lower insulation layer 412 may be disposed on the substrate 400, and a plurality of first conductive lines 420 extending in the second direction Y may be disposed on the lower insulation layer 412 to be spaced apart from each other in the first direction X. A plurality of first insulation patterns 422 may be disposed on the lower insulation layer 412 to fill the space between the plurality of first conductive lines 420. The plurality of first insulation patterns 422 may extend in the second direction Y. Upper surfaces of the plurality of first insulation patterns 422 may be positioned at the same level as the upper surfaces of the plurality of first conductive lines 420, respectively. The plurality of first conductive lines 420 may function as bit lines of the DRAM device 600.

In example embodiments, the plurality of first conductive lines 420 may include doped polysilicon, metal, conductive metal nitride, conductive metal silicide, conductive metal oxide, or a combination thereof. For example, the plurality of first conductive lines 420 may include, e.g., doped polysilicon, Al, Cu, Ti, Ta, Ru, W, Mo, Pt, Ni, Co, TiN, TaN, WN, NbN, TiAl, TiAlN., TiSi, TiSiN, TaSi, TaSiN, RuTiN, NiSi, CoSi, IrOx, RuOx, or a combination thereof, but may not be limited thereto. The plurality of first conductive lines 420 may include a single layer or a multilayer of the above-described materials. In example embodiments, the plurality of first conductive lines 420 may include a two-dimensional semiconductor material, e.g., grapheme, carbon nanotube, or a combination thereof.

The channel layer 430 may be disposed on the plurality of first conductive lines 420 to be spaced apart in the first direction X and the second direction Y, so that the channel layer 430 may be arranged to have a matrix shape. The channel layer 430 may have a first width in the first direction X, and a first height in the vertical direction Z. The first height may be greater than the first width. For example, the first height may be about 2 times to 10 times the first width, but may not be limited thereto. A lower portion of the channel layer 430 may function as a first source/drain region, and an upper portion of the channel layer 430 may function as a second source/drain region. A portion of the channel layer 430 between the first and second source/drain regions may function as a channel region.

In example embodiments, the channel layer 430 may include an oxide semiconductor. For example, the oxide semiconductor may include, e.g., InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, or a combination thereof. The channel layer 430 may include a single layer or a multilayer of the oxide semiconductor. In some examples, the channel layer 430 may have an energy band gap greater than an energy band gap of silicon. For example, the channel layer 430 may have an energy band gap of about 1.5 eV to 5.6 eV. For example, the channel layer 430 may have optimal channel performance when the channel layer 430 has the energy band gap of about 2.0 eV to 4.0 eV. For example, the channel layer 430 may be polycrystalline or amorphous, but may not be limited thereto. In some example embodiments, the channel layer 430 may include a two-dimensional semiconductor material, e.g., graphene, carbon nanotubes, or a combination thereof.

The gate electrode 440 may extend in the first direction X on both sidewalls of the channel layer 430. The gate electrode 440 includes a first sub-gate electrode 440P1 facing a first sidewall of the channel layer 430, and a second sub-gate electrode 440P2 facing a second sidewall opposite to the first sidewall of the channel layer 430. As the channel layer 430 is disposed between the first sub-gate electrode 440P1 and the second sub-gate electrode 440P2, the DRAM device may have a dual gate transistor structure. However, it may not be limited thereto. For example, the second sub-gate electrode 440P2 may not be formed, and only the first sub-gate electrode 440P1 facing the first sidewall of the channel layer 430 may be formed to form a single gate transistor structure.

The gate electrode 440 may include doped polysilicon, metal, conductive metal nitride, conductive metal silicide, conductive metal oxide, or a combination thereof. For example, the gate electrode 440 may include, e.g., doped polysilicon, Al, Cu, Ti, Ta, Ru, W, Mo, Pt, Ni, Co, TiN, TaN, WN, NbN, TiAl, TiAlN, TiSi, TiSiN., TaSi, TaSiN, RuTiN, NiSi, CoSi, IrOx, RuOx, or a combination thereof, but may not be limited thereto.

The gate insulation layer 450 may surround the sidewall of the channel layer 430, and may be interposed between the channel layer 430 and the gate electrode 440. For example, as shown in FIG. 28, an entire sidewall of the channel layer 430 may be surrounded by the gate insulation layer 450, and a portion of the sidewall of the gate electrode 440 may contact the gate insulation layer 450. In other example, the gate insulation layer 450 may extends in an extending direction of the gate electrode 440 (e.g., the first direction X), and may be disposed between the gate electrode 440 and the sidewalls of the channel layer 430. The gate insulation layer 450 may contact only the two opposing sidewalls of the channel layer 430.

In example embodiments, the gate insulation layer 450 may be formed of a silicon oxide layer, a silicon oxynitride layer, a high-k dielectric layer having a dielectric constant higher than a dielectric constant of the silicon oxide layer, or a combination thereof. The high-k dielectric layer may include metal oxide or metal oxynitride. For example, the high-k dielectric layer used as the gate insulation layer 450 may include, e.g., HfO₂, HfSiO, HfSiON, HfTaO, HfTiO, HfZrO, ZrO₂, Al₂O₃, or a combination thereof, but may not be limited thereto.

A plurality of second insulation patterns 432 may extend in the second direction Y on the plurality of first insulation patterns 422. The channel layer 430 may be interposed between two adjacent second insulation patterns among the plurality of second insulation patterns 432. A first buried layer 434 and a second buried layer 436 may be disposed in a space between two adjacent channel layers 430 between two adjacent second insulation patterns 432. The first buried layer 434 may be disposed on a bottom of the space between two adjacent channel layers 430, and the second buried layer 436 may be disposed on the first buried layer 434 to fill a remaining space between the two adjacent channel layers 430. An upper surface of the second buried layer 436 may be disposed at the same level as an upper surface of the channel layer 430, and the second buried layer 436 may cover a surface of the gate electrode 440. In some example embodiments, the plurality of second insulation patterns 432 may include the same material as a material of the plurality of first insulation patterns 422. The plurality of second insulation patterns 432 and the plurality of first insulation patterns 422 may be continuously formed. In some example embodiments, the second buried layer 436 may include the same material as a material of the first buried layer 434. The first and second buried layer 436 may be continuously formed.

A capacitor contact 460 may be disposed on the channel layer 430. The capacitor contact 460 may vertically overlap the channel layer 430. A plurality of capacitor contacts 460 may be arranged in a matrix shape in which the capacitor contacts 460 are spaced apart from each other in the first direction X and the second direction Y. The capacitor contact 460 may include, e.g., doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN., RuTiN, NiSi, CoSi, IrOx, RuOx, or a combination thereof, but may not be limited thereto. The upper insulation layer 462 may be on the plurality of second insulation patterns 432 and the second buried layer 436, and the upper insulation layer 462 may surround a sidewall of the capacitor contact 460.

The etch stop layer 106 may be disposed on the upper insulation layer 462. The capacitor 170 may pass through the etch stop layer 106, and may contact the capacitor contact 460.

The capacitor 170 includes the lower electrode 130, the dielectric layer 140, the first upper electrode 150, and the second upper electrode 152. A bottom of the lower electrode 130 may contact the capacitor contact 460 serving as a landing pad. The plate electrode 160 may be formed on the first and second upper electrodes 150 and 152.

In example embodiments, the capacitor may be substantially the same as the capacitor described in FIG. 1. In example embodiments, the capacitor may be substantially the same as the capacitor described in FIG. 13.

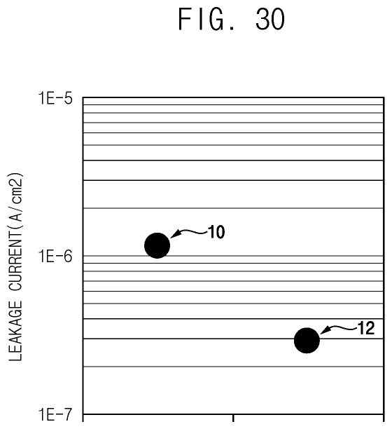

FIG. 30 illustrates leakage current characteristics of a capacitor according to an embodiment and a capacitor according to a comparative example.

In FIG. 30, the capacitor according to the embodiment includes a lower electrode, a dielectric layer, and first and second upper electrodes. In example embodiments, the first upper electrode may include TiN further including Ni, and the second upper electrode may include Ni. For example, the first upper electrode may be formed of TiN and Ni, and the second upper electrode may be formed of Ni. The lower electrode includes TiN.

The capacitor according to the comparative example includes a lower electrode, a dielectric layer, and an upper electrode. The lower electrode and the dielectric layer may have the same structure and the same material as the lower electrode and the dielectric layer of the capacitor according to the embodiment, respectively. The upper electrode includes a single layer of TiN, and the second upper electrode is not formed.

Referring to FIG. 30, reference numeral 12 represents leakage currents of the capacitor according to the embodiment, and reference numeral 10 represents leakage currents of the capacitor according to the comparative example.

Under the same voltage conditions, the leakage currents of the capacitor according to the embodiment are lower than the leakage currents of the capacitor according to the comparative example. Accordingly, the capacitor according to the embodiment may have improved electrical characteristics.

Although example embodiments of the present invention have been described above, it will be understood by those of ordinary skill in the art that various changes and modifications can be made to the present invention without departing from the idea and scope of the present invention as set forth in the appended claims.

What is claimed is:

1. A semiconductor device, comprising:
a substrate; and
a capacitor on the substrate,
wherein the capacitor includes:
a lower electrode;
a dielectric layer on the lower electrode, the dielectric layer including a metal oxide;
a first upper electrode on the dielectric layer, the first upper electrode including a metal nitride further including a first material having a work function of 4.8 eV or more; and
a second upper electrode on the first upper electrode, the second upper electrode including the first material.

2. The semiconductor device of claim 1, wherein the first material has the work function higher than a work function of the metal nitride included in the first upper electrode.

3. The semiconductor device of claim 1, wherein the metal nitride included in the first upper electrode includes TiN, TiSiN, TaN, TaSiN, NbN or NbSiN.

4. The semiconductor device of claim 1, wherein the first material includes Ni, Pd, Ir, or Pt.

5. The semiconductor device of claim 1, wherein the first material included in the first upper electrode is the same as the first material included in the second upper electrode.

6. The semiconductor device of claim 1, wherein a concentration of the first material included in the first upper electrode gradually decreases in a direction from an upper surface of the first upper electrode toward the dielectric layer.

7. The semiconductor device of claim 1, wherein:
the second upper electrode is discontinuously formed on the first upper electrode, and
the second upper electrode includes a plurality of first materials having an isolated island shape to be spaced apart from each other.

8. The semiconductor device of claim 1, wherein a thickness of the first upper electrode is about 20 cÅ to about 50 Å.

9. The semiconductor device of claim 1, wherein a thickness of the second upper electrode is less than a thickness of the first upper electrode.

10. A semiconductor device, comprising:
a substrate;
a lower structure on the substrate; and
capacitors on the lower structure,
wherein the capacitors includes:
a plurality of lower electrodes on the lower structure, each of the lower electrodes having a pillar shape;
a dielectric layer on surfaces of the lower electrodes and the lower structure;
a first upper electrode on the dielectric layer, the first upper electrode covering an entire surface of the dielectric layer, and the first upper electrode including a metal nitride further including a first material having a work function higher than a work function of the metal nitride; and
a second upper electrode partially covering a surface of the first upper electrode, the second upper electrode including the first material,
wherein a portion of the dielectric layer and a space in contact with the portion of the dielectric layer are formed between the lower electrodes, and
wherein the first upper electrode and the second upper electrode partially fill the space between the lower electrodes.

11. The semiconductor device of claim 10, wherein the metal nitride included in the first upper electrode includes TiN, TiSiN, TaN, TaSiN, NbN, or NbSiN.

12. The semiconductor device of claim 10, wherein the first material is a metal having the work function of 4.8 eV or more.

13. The semiconductor device of claim 10, wherein the first material includes Ni, Pd, Ir, or Pt.

14. The semiconductor device of claim 10, wherein a concentration of the first material included in the first upper electrode gradually decreases in a direction from an upper surface of the first upper electrode toward the dielectric layer.

15. The semiconductor device of claim 10, wherein a thickness of the first upper electrode is about 20 Å to about 50 Å.

16. The semiconductor device of claim 10, further comprising:
a plate electrode on the first and second upper electrodes,
wherein the plate electrode completely fills the space with the first and second upper electrodes between the lower electrodes.

17. The semiconductor device of claim 10, further comprising:
a support layer pattern surrounding surfaces of the lower electrodes.

18. A semiconductor device, comprising:
cell transistors on a substrate, each of the cell transistors including a gate structure, a first impurity region, and a second impurity region;
bit line structures respectively electrically connected to the first impurity region of each of the cell transistors;
first conductive patterns on the bit line structures, respectively,
second conductive patterns between the bit line structures, the second conductive patterns respectively electrically connected to each of the first conductive patterns and the second impurity region of each of the cell transistors; and
capacitors disposed on the first conductive patterns, respectively,
wherein the capacitors include:
lower electrodes having pillar shapes, the lower electrodes contacting the first conductive patterns, respectively;
a dielectric layer on surfaces of the lower electrodes;
a first upper electrode covering an entire surface of the dielectric layer, the first upper electrode including a metal nitride further including a first material having a work function of 4.8 eV or more; and
a second upper electrode forming discontinuously on a surface of the first upper electrode, the second upper electrode including the first material.

19. The semiconductor device of claim 18, wherein the first material includes Ni, Pd, Ir or Pt.

20. The semiconductor device of claim 18, wherein a concentration of the first material included in the first upper electrode gradually decreases in a direction from an upper surface of the first upper electrode toward the dielectric layer.
